(19) United States
(12) Patent Application Publication
(10) Pub. No.: US 2005/0034040 A1
(43) Pub. Date: Feb. 10, 2005

(54) System and method for self-adaptive redundancy choice logic

(75) Inventor: Jiann-Jyh (James) Lay, Kaohsiung City (TW)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Broadcom Corporation

(21) Appl. No.: 10/750,961

(22) Filed: Jan. 5, 2004

Related U.S. Application Data
(60) Provisional application No. 60/492,957, filed on Aug. 7, 2003.

(51) Int. Cl. G01R 31/28

(52) U.S. Cl. 714/733

(57) ABSTRACT

A system and method for self-adaptive redundancy choice logic uses BIST data to determine if a memory is functional. If a portion of the memory is not functional, the system and method selects a redundant memory section for use. A BIST is then run a second time to confirm the functionality of the selected redundant memory section.

### PRIORITY REFERENCE TO PRIOR APPLICATION

This application claims benefit of and incorporates by reference U.S. Patent application No. 60/492,957, entitled “SRAM SELF-ADAPTIVE REDUNDANCY CHOICE LOGIC,” filed on Aug. 7, 2003, by inventor Jiann-Jyh (James) Lay.

### BACKGROUND OF THE INVENTION

1. Technical Field

This invention relates generally to memory devices, and more particularly, but not exclusively, to the automatic selection of redundant memory during a partial memory failure.

2. Description of the Related Art

Integrated circuits (ICs), also referred to as chips, generally include a built-in self test (BIST) to test chip memory, thereby confirming functionality. The BIST can generally identify sections of the memory that are nonfunctional and output the identified sections per IEEE 1149.1 protocols or other techniques. If a BIST indicates memory is nonfunctional, the IC housing the memory must be disposed of or repaired. Disposal lowers the yield rate for a chip manufacturing process, thereby increasing costs on a per chip basis. In contrast, repairing defective chips increases the yield but can also be time consuming and inefficient. For example, repair may require an engineer to analyze chip failure data to determine if laser-repair or other repair techniques are viable. If a repair technique is viable, the engineer must then perform the repair and redo the BIST to confirm the repair.

In addition, using a BIST may require reserving several pins on a chip since not only must pass/fail information be outputted, but also specific defect data must be outputted so that an engineer will have enough information to implement an appropriate repair of the memory on the chip.

Accordingly, a new system and method are needed that increases IC manufacturing yield while decreasing the need for engineer intervention during the manufacturing process.

### SUMMARY OF THE INVENTION

Embodiments of the invention provide a system and method for automatic selection of redundant memory sections during a partial memory failure. One embodiment of the system includes a BIST and self-adaptive logic communicatively coupled to the BIST. The BIST determines if a memory is functional and the self-adaptive logic selects a redundant memory section if a portion of the memory is determined to be nonfunctional. The BIST then determines if at least the selected redundant memory is functional.

An embodiment of the method comprises determining if a memory is functional based on memory BIST data; selecting a redundant memory section if a portion of the memory is determined to be nonfunctional; and determining if at least the selected redundant memory is functional according to a BIST.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a block diagram illustrating an integrated circuit according to an embodiment of the invention;

FIG. 2 is a diagram illustrating output of a BIST of the Integrated Circuit of FIG. 1;

FIG. 3 is a block diagram illustrating self-adaptive logic of the Integrated Circuit of FIG. 1;

FIG. 4 is a diagram illustrating register data of a register of the Integrated Circuit of FIG. 1; and

FIG. 5 is a flowchart illustrating a method of automatic selection of redundant memory during a partial memory failure.

### DETAILED DESCRIPTION OF THE ILLUSTRATED EMBODIMENTS

The following description is provided to enable any person having ordinary skill in the art to make and use the invention, and is provided in the context of a particular application and its requirements. Various modifications to the embodiments will be readily apparent to those skilled in the art, and the generic principles defined herein may be applied to other embodiments and applications without departing from the spirit and scope of the invention. Thus, the present invention is not intended to be limited to the embodiments shown, but is to be accorded the widest scope consistent with the principles, features and teachings disclosed herein.

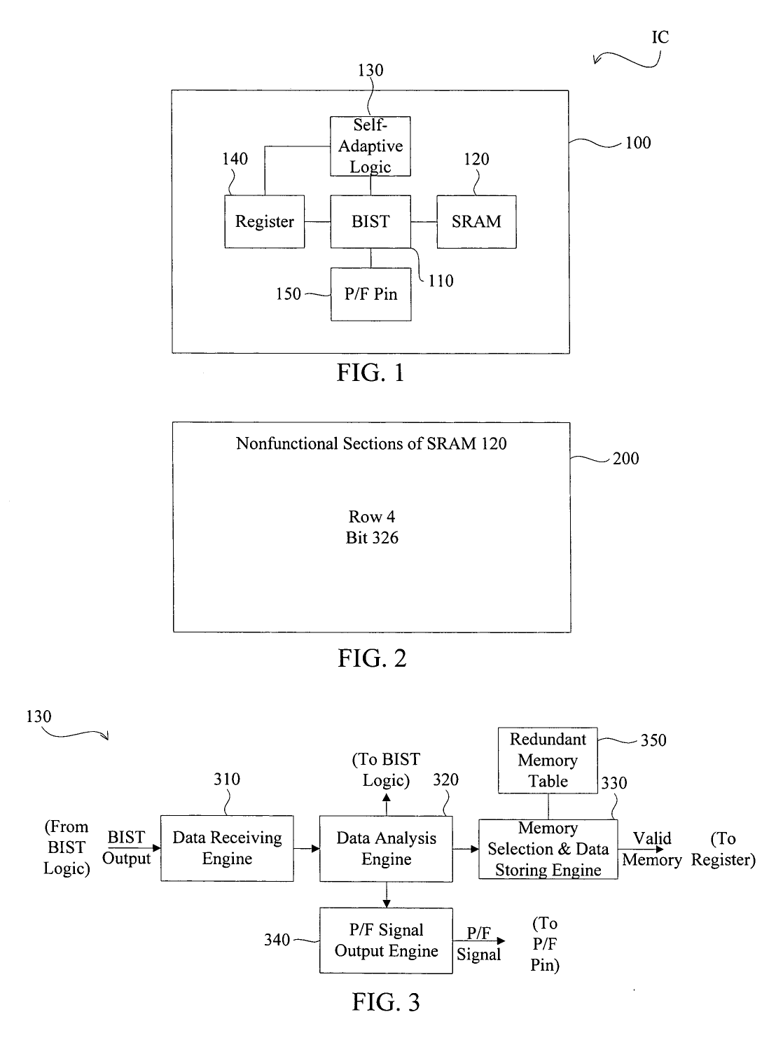

FIG. 1 is a block diagram illustrating an integrated circuit 100 according to an embodiment of the invention. The integrated circuit 100 includes a BIST 110 that is communicatively coupled to a static random access memory (SRAM) 120, self-adaptive logic 130, a register 140 and a pass/fail (P/F) pin 150. Further, the self-adaptive logic is also communicatively coupled to the register 140. Additional logic (not shown) may also be disposed on the integrated circuit 100 and communicatively coupled to one or more of the components shown in FIG. 1. For example, additional logic may use the SRAM 120 and therefore be communicatively coupled to the SRAM 120 and the register 140, which indicates what portions of the SRAM 120 are functional.

The BIST 110 tests a portion of the SRAM 120 indicated as functional by the register 140 and outputs test results to the self-adaptive logic 130 and the P/F pin 150. If no portion of the SRAM 120 is listed in the register 140, the BIST 110 can test a default portion of the SRAM 120. The BIST 110 can use any test technique without the need to resort to external test resources. The BIST 110 can also include a multi-input signature register to capture the SRAM 120 test results and compress them into an overall value referred to as a test signature. Output of the BIST 110 will be discussed in further detail in conjunction with FIG. 2 below.

The SRAM 120 is memory that is used by other logic (not shown) on the integrated circuit 100 or used by another integrated circuit or device that can be communicatively coupled to the integrated circuit 100. It will be appreciated by one of ordinary skill in the art that other types of memory, such as Dynamic Random Access Memory (DRAM), can be used in place of the SRAM 120.

The self-adaptive logic 130, as will be discussed further in conjunction with FIG. 3 below, can comprise software, an application specific integrated circuit (ASIC), or other technology. The self-adaptive logic 130 receives the SRAM 120 test results from the BIST 110 and selects redundant memory (bits, rows or columns) within the SRAM 120 if the test results indicate that some of the currently selected memory cells are non-functional. The self-adaptive logic 130 also stores data indicating which sections of the SRAM 120 are functional in the register 140 for use by the BIST 110 and other logic (not shown) on the integrated circuit 100 or otherwise capable of being communicatively coupled to the integrated circuit 100.

The register 140 includes a memory device that stores data indicating which portions of the SRAM 120 are functional and can be used, either by the BIST 110 for testing or for other logic on the integrated circuit 100 or otherwise capable of being communicatively coupled to the integrated circuit 100. In another embodiment of the invention, the register 140 indicates which sections of the SRAM 120 are nonfunctional and therefore are not to be used.

The P/F pin 150 includes a pin that outputs a signal indicating if the SRAM 120 is functional (e.g., at least the minimum amount of memory of the SRAM 120 is functional) when it receives appropriate output from the BIST 110. The signal can be an active low or any other signal that can be interpreted by a device coupled to the integrated circuit 100. In an embodiment of the invention, the P/F pin 150 can be replaced with a different type of output device that can indicate the functionality of the SRAM 120. For example, a light emitting diode (LED) can be used to emit a light when the SRAM 120 is determined to be functional per the BIST 110. Based on the output of the P/F pin 150, the integrated circuit 100 can be discarded if the SRAM 120 sequentially fails the BIST 110 testing (i.e., when self repair via redundant memory selection fails) during production.

It will be appreciated by one of ordinary skill in the art that the various components of the integrated circuit 100 can combined in various ways in place of being separate components as shown in FIG. 1. For example, the self-adaptive logic 130 and the BIST 10 can be combined into a single ASIC. Further, the SRAM 120 and the register 140 can be combined into a single memory device. Alternatively, the register 140 can be combined with the self-adaptive logic 130.

During operation, e.g., manufacturing or power on of the integrated circuit 100, the BIST 110 initially performs a test of the SRAM 120. The test can be of the default memory sections in the SRAM 120 or of memory sections indicated as functional in the register 140. The BIST 110 then outputs a pass/fail signal to the P/F pin 150 (or other output device) that outputs a pass or fail signal as a result of the testing. In addition, the BIST 110 outputs more specific test results, as will be discussed further in conjunction with FIG. 2 below, to the self-adaptive logic 130 that indicates which, if any, memory sections of the SRAM 120 are nonfunctional.

The self-adaptive logic 130 receives the specific test results from the BIST 110 indicating, which, if any, of the memory sections of the SRAM 120 are nonfunctional. The self-adaptive logic 130 then selects redundant memory sections of the SRAM 120 to use in place of the non-functional memory cells identified by the BIST 10. The self-adaptive logic 130 then stores a list (or other data structure) of functional memory sections in the register 140.

The BIST 110 then retests the SRAM 120 using the memory sections specified in the register 140 (or just the selected redundant sections) and again outputs a pass/fail signal to the P/F pin 150 and more specific results to the self-adaptive logic 130. If the BIST 110 indicates a pass (i.e., the redundant memory selection by the self-adaptive logic 130 has been successful) then no further tests are run and the SRAM 120 is ok for use. If the BIST 110 indicates a failure the second time, then the SRAM 120 is not acceptable for use and the integrated circuit 100 can be discarded or undergo laser repair. In another embodiment of the invention, the self-adaptive logic 130 can continue to attempt selecting alternative redundant memory sections (if any) until the SRAM 120 is determined to be functional by the BIST 110 or until all redundant memory sections have been tested.

In another embodiment of the invention, the BIST 110 can output specific bits in the SRAM 120 that are nonfunctional. The self-adaptive logic 130 can then store the location of functional bits in the register 140. Other logic that then uses the SRAM 120 will simply avoid using the nonfunctional bits specified in the register 140. Further, redundant bits can also be specified in the register 140.

FIG. 2 is a diagram illustrating output 200 of the BIST 110 of the Integrated Circuit 100 (FIG. 1) to the self-adaptive logic 130. The output 200 specifies which sections of the SRAM 120 are nonfunctional. In one embodiment, the output 200 can specify an entire column or row of the SRAM 120 (e.g., row 4) that is nonfunctional. In another embodiment of the invention, the output 200 can also or alternatively indicate specific nonfunctional bits in the SRAM 120. When a low resolution is used (e.g., columns or rows), redundant rows or columns must be selected by the self-adaptive logic 130. When a higher resolution is used (e.g., bits), bad bits can be listed in the register 140 and therefore avoided by other logic. Alternatively, redundant bits can also be specified in the register 140.

FIG. 3 is a block diagram illustrating the self-adaptive logic 130 of the Integrated Circuit 100 (FIG. 1). The self-adaptive logic 130 can be implemented in software, as an ASIC or via other techniques or combinations of techniques. The self-adaptive logic 130 comprises a data receiving engine 310 communicatively coupled to a data analysis engine 320, which is communicatively coupled to a memory selection & data storing engine 330 and a P/F signal output engine 340. The memory selection & data storing engine 330 is communicatively coupled to a redundant memory table 350.

The data receiving engine 310 receives test data, such as the BIST output 200, from the BIST 110. The test data can specify nonfunctional columns or rows of the SRAM 120 or individual bits of the SRAM 120 that are nonfunctional. The data analysis engine 320 processes the received data to determine if the SRAM 120 is functional (e.g., the minimal amount of memory of the SRAM 120 is functional). If the SRAM 120 is determined to be fully functional, the data analysis engine outputs a positive signal to the P/F signal output engine 340, which then outputs a positive signal via the P/F pin 150.

If the SRAM 120 is determined to have nonfunctional memory sections (row, columns, or individual bits), the data analysis engine 320 forwards the data to the memory selection & data storing engine 330, which then selects redundant memory of the SRAM 120 by accessing the redundant memory table 350 and stores data indicating the selection and other functional sections in the register 140. The memory selection & data storing engine 330 can also update the table 350 to indicate that the selected memory section(s) are no longer redundant. The data analysis engine 320 also informs the BIST 110 that it will need to perform another test of the SRAM 120 using the sections of the SRAM 120 specified in the register 140 (or just the selected redundant sections specified in the register 140).

In an embodiment of the invention, the memory selection & data storing engine 330 selects redundant rows and/or columns in the SRAM 120 for future use to compensate for nonfunctional row and/or columns and stores data identifying the functional rows and/or columns in the register 140. In another embodiment of the invention, the memory selection & data storing engine 330 selects redundant bits and stores data indicating the functional bits of the SRAM 120 in the register 140. Further, it will be appreciated by one of ordinary skill in the art that the redundant memory table 350 can be in the form of any data structure, such as a linking list.

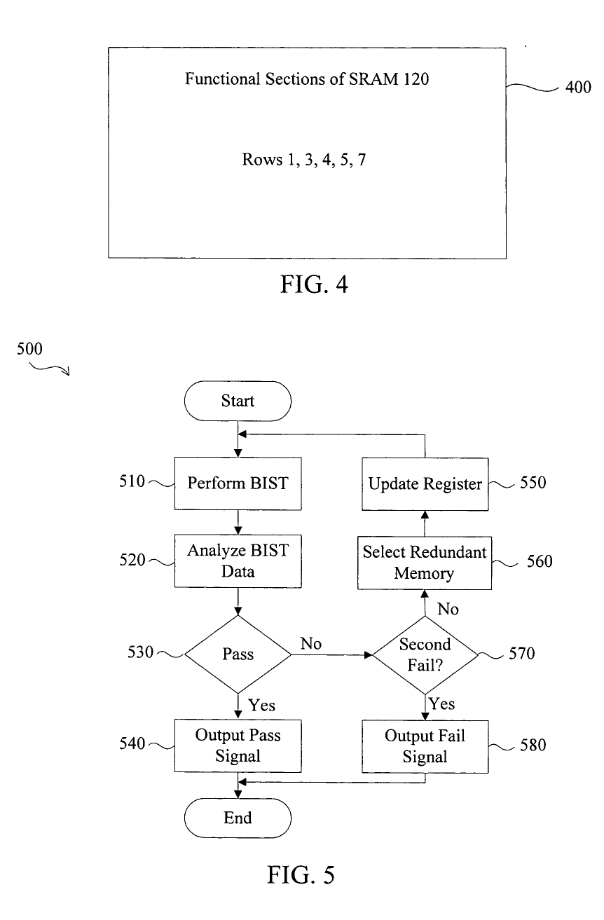

FIG. 4 is a diagram illustrating the register data 400 of the register 140 of the Integrated Circuit 100 (FIG. 1). The register data 400 indicates what sections (e.g., rows, columns and/or bits, etc.) of the SRAM 120 are functional. In another embodiment of the invention, the register data 400 indicates what sections are nonfunctional and therefore should not be used. The BIST 110 uses the register data 400 to determine which sections of the SRAM 120 to test, i.e., the BIST 110 will test selected functional sections of the SRAM 120 as identified in the register data 400 to confirm their functionality. If the register data 400 is empty, then the BIST 110 will test default sections of the SRAM 120.

Other logic on the integrated circuit 100 or otherwise communicatively coupled to the integrated circuit 100 uses the register data 400 to determine what sections of the SRAM 120 are functional and therefore can be used. In an alternative embodiment in which the register 400 data indicates what sections are nonfunctional, the other logic can use the register 400 data to determine which sections of the SRAM 120 should not be used.

FIG. 5 is a flowchart illustrating a method 500 of automatic selection of redundant memory during a partial memory failure. During production testing or power up, a BIST is first performed (510) on memory (e.g., the SRAM 120). The BIST can be of default memory sections or memory sections indicated as functional in a register (e.g., the register 140). The data from the BIST is then analyzed (520) to determine if the memory sections tested are functional. If the memory passes (530), then a pass signal is outputted (540) via a pin (e.g., the P/F pin 150) or via other device (e.g., LED). The method 500 then ends.

If the memory does not pass (530) then if this is a second failure (570) of the memory then a fail signal is outputted (580) via a pin (e.g., the P/F pin 150) or via other device. The method 500 then ends. If this is not a second failure (570) then redundant memory sections are selected (560) from a data structure listing redundant memory sections (e.g., the redundant memory table 350), which can include rows, columns and/or bits in the memory. A register storing data corresponding to functional sections of the memory is then updated (550) based on the selection (560) and the BIST is then performed (510) again to verify that the selected redundant sections are functional. The other functional sections listed in the register can also be retested. Further, in an embodiment of the invention, a data structure (e.g., the redundant memory table 350) can also be updated to indicate what memory sections have been selected and are therefore no longer redundant.

In an embodiment of the invention, additional attempts at redundant memory selection (560) can be performed even if a second BIST failure (570) has occurred. In another embodiment of the invention, the updating (550) can update a register to indicate nonfunctional regions of the memory in place of functional regions of the memory.

Accordingly, embodiments of the invention offer significant improvements over the conventional art. For example, only a single output pin (P/F pin 150) to output a pass/fail signal is required in contrast to conventional techniques that require a plurality of output pins to specify test results so that memory could be repaired. In addition, since the self-adaptive logic 130 is capable of selecting redundant memory sections without human intervention, costs will decrease while manufacturing yield will increase. Further, integrated circuits or other devices employing embodiments of the invention will have longer lifetimes as the self-adaptive logic 130 compensates for failed memory sections by automatically selecting redundant memory sections during power up.

The foregoing description of the illustrated embodiments of the present invention is by way of example only, and other variations and modifications of the above-described embodiments and methods are possible in light of the foregoing teaching. Components of this invention may be implemented using a programmed general purpose digital computer, using application specific integrated circuits, or using a network of interconnected conventional components and circuits. Connections may be wired, wireless, modem, etc. The embodiments described herein are not intended to be exhaustive or limiting. The present invention is limited only by the following claims.

1. A method, comprising:
determining if a memory is functional based on memory BIST data;
selecting a redundant memory section if a portion of the memory is determined to be nonfunctional; and
determining if at least the selected redundant memory is functional according to a BIST.

2. The method of claim 1, further comprising storing data indicating the selected redundant memory section.

3. The method of claim 1, further comprising outputting a pass or fail signal based on the determining if at least the selected redundant memory is functional according to a BIST.

4. The method of claim 1, wherein the redundant memory section includes a column or row.

5. The method of claim 1, wherein the redundant memory section includes a bit.

6. The method of claim 1, wherein the selecting selects a redundant memory section from a redundant memory data structure.

7. The method of claim 6, further comprising updating the redundant memory data structure to indicate that the selected redundant memory section is no longer redundant.

8. The method of claim 1, wherein the method is performed during a manufacturing process.

9. The method of claim 1, wherein the method is performed during power up of an integrated circuit.

10. A system, comprising:
means for determining if a memory is functional based on memory BIST data;
means for selecting a redundant memory section if a portion of the memory is determined to be nonfunctional; and
means for determining if at least the selected redundant memory is functional according to a BIST.

11. A system, comprising:
a BIST capable of determining if a memory is functional; and
self-adaptive logic, communicatively coupled to the BIST, capable of selecting a redundant memory section if a portion of the memory is determined to be nonfunctional;
wherein the BIST is further capable of determining if at least the selected redundant memory is functional.

12. The system of claim 11, further comprising a register communicatively coupled to the self-adaptive logic and wherein the self-adaptive logic is further capable of storing data indicating the selected redundant memory section in the register.

13. The system of claim 11, further comprising a pin and wherein the self-adaptive logic if further capable of outputting a pass or fail signal based on the BIST determination of the functionality of the selected redundant memory.

14. The system of claim 11, wherein the redundant memory section includes a column or row.

15. The system of claim 11, wherein the redundant memory section includes a bit.

16. The system of claim 11, further comprising a redundant memory data structure listing redundant memory sections and wherein the self-adaptive logic selects a redundant memory section from the redundant memory data structure.

17. The system of claim 11, wherein the self-adaptive logic is further capable updating the redundant memory data structure to indicate that the selected redundant memory section is no longer redundant.

18. The system of claim 11, wherein the BIST and the self-adaptive logic function during a manufacturing process.

19. The system of claim 11, wherein the BIST and the self-adaptive logic function during power up of the system.
